(19) United States
(12) Patent Application Publication
(10) Pub. No.: US 2003/0110431 A1
(43) Pub. Date: Jun. 12, 2003

(54) Scanning an allowed value into a group of latches

(75) Inventors: Andrew Douglas Davies, Rochester, MN (US); Daniel Lawrence Stasiak, Rochester, MN (US)

Correspondence Address: Robert R. Williams, IBM Corporation, Dept. 917, 3605 Highway 52 North, Rochester, MN, 55901-7829, US

(73) Assignee: International Business Machines Corporation, Armonk, NY

(21) Appl. No.: 10/016,701

(22) Filed: Dec. 10, 2001

(51) Int. Cl. G01R 31/28

(52) U.S. Cl. 714/726

(57) ABSTRACT

During scan testing of logical and memory circuits, it is important to prevent a scan test error resulting from simultaneous switching of the values within chip logic. Scan testing, however, encompasses rapidly scanning in values into a register to detect if the register is properly functioning. A circuit is disclosed which looks at the n−1 values within the register and determines if the next scan in value would cause contention. If so, that value is blocked until the next scan in value would not cause contention with the n−1 values within the register. Practicably, the invention will allow only allowed values into the register and may allow a “hot one” value into the register every n−1 clock cycle. Feedback of the values in the register is provided to a logical AND function to determine if a differing bit value will be allowed to scan into the register.

### TECHNICAL FIELD

This invention relates generally to the field of microprocessor logic and latches, and more particularly relates to an apparatus and a method to increase the speed of electronic logic while preventing contention in multiplexers (muxes).

### BACKGROUND OF THE INVENTION

To decrease the costs of repairing computer chips in the field, chip manufacturers have come to test the chips before they become integrated into a product. Immediately after manufacture it may cost only $1 to test a chip and discover that it is faulty; however, once the faulty chip has been implemented into a computer already sold to a customer and in use, it may cost thousands of dollars as well as the cost of the downtime for the customer using the computer to replace the defective chip.

The testing of these chips as large scale integration (LSI) packages, very large scale integration (VLSI) packages and application specific integrated circuits (ASIC) has become increasingly important as these components and circuits continue to increase in gate densities. One procedure to test the logic of computer chips, and especially microprocessors, is to rapidly input, also called scanning, known values into the circuits and monitor the output. Such tests are known as Array Built In Self Test (ABIST) to test memory arrays and Logic Built In Self Test (LBIST) to test the logic of microprocessors. Variations of LBIST may include a Level Sensitive Scan Design (LSSD) test to scan the boundaries of a logic net.

Simplified, scan testing is accomplished by withholding the system clock signals and then switching to “shift mode” by rapidly inputting a sequence of desired logic test signals into and shifted to the appropriate latches. When this is done, the latch states provide the desired stimuli for the testing of the related logic circuits, also called nets. Next, the test patterns are propagated through the nets by executing one or more steps of the “function mode” operation which uses the system clock. The response patterns of the logic networks to the applied test signals are captured by the system latches in a known manner depending on certain details of hardware design, often replacing the original input test patterns. Then the system reverts to the shift-mode operation output the response patterns for examination. By comparing the known input with the expected output, one can determine if the circuitry operates properly.

A typical scan design approach can be seen in the scan design circuit 110 of FIG. 1. Logic 112 has multiple data inputs 114, and generates outputs to latches 116, 118, 120. Typically during normal operation, the data is input in parallel and during scan testing, the test data is input sequentially. Logic 122 receives inputs from latches 116, 118, 120 and generates outputs to latches 124, 126, 128. Logic 130 receives inputs from latches 124, 126, 128 and has multiple outputs 132 to output the data. Each of the latches 116, 118, 120, 124, 126, 128 in circuit 110 is really two latches, of which one is a D-type flip-flop having a data (D) input for receiving system data and the other receives logic test patterns as scan data input signals on line 134. The latches continually shift the Q output to the SD input of the next daisy-chained latch. The shift occurs each time an active pulse of the clock signal on line 136 is received at the clock (CLK) input when the scan enable (SE) input is set by the scan enable signal on line 138 to acknowledge the scan data rather than the system data. Each of the daisy-chained latches shifts its current bit to the next latch until the entire logic test pattern has been shifted in. The D inputs can then receive inputs from the logic circuits when the scan enable (SE) input is set by the scan enable signal on line 138 to acknowledge the system data rather than the scan data. The system data is then stored in parallel in the testing of system design logic. The latched results of the test are then shifted out at output on line 140 to be compared to expected simultaneous switching during concurrent scan testing, by test pattern results.

With every successive generation of integrated circuits having a greater number of gates to test and faster operating frequencies, simultaneous switching concerns in systems utilizing scan-based testing become more prevalent. The logic implemented in the circuits today, moreover, may be dynamic logic which means that the transistors in the circuits are precharged on one clock cycle and then, depending upon the input signal, are discharged rapidly on the next clock cycle. Dynamic logic is much faster than static logic in which each transistor must charge and discharge on the same clock cycle. Simultaneous switching occurs when two or more signals are input at the same time into a latch and the latch experiences either two high signals, two low signals, or a low signal and a high signal and the resulting electrical noise caused by the simultaneous scan shifting can cause corrupted test results. Therefore, it is desirable to reduce simultaneous switch concerns in scan-based testing techniques.

Referring now to FIG. 2 which is a typical configuration of logic elements, such as in a fixed point unit in a microprocessor: a decoder 250 drives a set of muxes within the rotator 270 which may be followed by other logic elements 280. The two latches 220 and 222 would comprise the one latch 116 of FIG. 1. Also, the dynamic decoder 250 and the dynamic rotator 270 could comprise logic 122 of FIG. 1. Following latches 220, 230, 240, the decoder 250 generates the select signals 260 select(0:7) in parallel for a set of muxes (not shown) implemented within the rotator 270. The rotator 270 rotates the signals Data(0:63) 262 by the value held in signal 260 select(0:7). The muxes within the rotator 270 may be driven only by a “hot one” set of select signals, i.e., only one of the select signals 260 select(0:7) may be high or active during a clock cycle and all the others must be low or inactive. This condition is necessary during scan testing because if more than one select signal is active, there is a possibility that two branches inside the mux are on, one trying to pull a node high, the other trying to pull the node low, which resulting in an invalid condition, as discussed above in the simultaneous switching case. Because the output of the mux within rotator 270 cannot be predicted during simultaneous switching, the mux element is not testable.

To avoid the concerns of simultaneous switching, the decoder 250 must be placed after the latches 220, 222, 230, 232, 240, 242 so that under test conditions when the latches 220, 222, 230, 232, 240, 242 are being scanned with random binary data, only one of the select signals 260 select(0:7) is a “hot one” presented to the muxes of the rotator 270. If the timing path 212 between latches 220, 230, 240 and latch K1 280 is not making the required product operating cycle time, the designer is faced with a difficult problem. He/she may not be able to simply move the decoder before the latches to a timing path 310 between the static logic 210 and latches 220-242 which typically has a lot of extra slack because he/she needs to have “hot one” inputs to the muxes within the rotator 270. Simultaneously, the designer may not be able to speed up the path of which the decoder and muxes are a part.

A fix for this timing problem can be attempted by moving the decoder 350 into the previous cycle path 310 as shown in FIG. 3 in which the dynamic decoder 250 is converted to static decode logic 350. The static decoder 350 outputs signals 330 select latch(0:7) to a scannable K0 register 320 and scannable K1 register 322. The output signals 324 select_k0(0:7) of the K0 register 320 feeds the K1 dynamic rotator 270. Thus, the timing problem is solved but a new problem is created when testing. The latches of K0 register 320 and of K1 register 322 must be scannable to insure a high random test coverage on the rotator 270. During scan operation when random patterns of ones and zeros are fed through the scan chain, the select latches 320, 322 can have more than one bit at a high level at the same time, i.e., the “hot one” requirement may not be satisfied.

Recall that the muxes within the rotator 270 require that the input signal 324 called select_k0(0:7)=00000000 or only one bit =“1,” i.e., either only one bit of the eight bit sequence can be “hot” or have a value of “1;” or all the bits must have a value of zero; these are the allowed states. The importance of the “hot one” requirement for dynamic logic is demonstrated in FIG. 4. The mux 410 of FIG. 4 is contained within the K1 dynamic rotator 270 of FIG. 3. During scan the value input at signal 324 select_k0(0) cascades down to signals 324 select_k0(1:7). A problem arises if, for example, signal 324 select_k0(0:7)=11000000 and signal 340 data(0) is low and signal 342 data(1) is high. A contention arises because signal 340 data(0) at inverter 440 is trying to pull the precharge node 420 high while another signal 342 data(1) at inverter 442 is pulling the precharge node 420 low. The state of the precharge node 420 thus becomes unknown. If, however, only one bit in signal 324 select_k0(0:7) is high or none are high, the value at the output 272 of the mux is known. Thus, prior art solutions to maintain a hot one or all zero values within the select latch during scan mode and which still allow random values to scan through the scan string have constrained the decode and rotate function within the timing path. Many styles of muxes demonstrate this problem. The need for “hot one” select signals is a very general problem.

There is thus a need in the industry to be able to accomplish scan testing of microprocessor components without the risk of simultaneous switching.

### SUMMARY OF THE INVENTION

These needs and others that will become apparent to one skilled in the art are satisfied by a circuit to prevent contention in logic whose input derives from a scannable register, comprising: a register having a plurality of latches having an input signal; control logic also having the input signal which gates the input signal to the register so that the register may have only an allowed value; and a feedback wherein some or all of an output of the register are used to control the control logic. There may be different allowed values depending upon the signals and the circuits, e.g., the allowed value may be that all the latches have a value of zero; or that only one latch has a value of one. Alternatively, the allowed value may be that all the latches have a value of one; or that only one of the latches has a value of zero.

The control may comprise an logical AND function which can be made up of a myriad of logical AND, NAND, NOR, OR gates configured to achieve the logical AND function. The logic in which to prevent contention may be dynamic logic, or it may be static logic.

The invention may further be the method to perform a scan test, the method comprising the steps of: determining acceptable values to be scanned into a register that will prevent simultaneous switching; determining if a scan function is occurring; determining if a sequence of bits to be scanned into the latches of register is not an acceptable value; gating the sequence of bits to be scanned into the register; scanning in an acceptable value into the register; providing feedback of the values of the bits in the register; comparing the values of bits in the register to the next bit to be scanned in; and preventing the next bit from being scanned into the register if it is not an acceptable value.

Simply, the invention is a method for inserting a “hot one” bit value into the register of n latches only every nth clock cycle; or a method for inserting a “cold zero” bit value into the register of n latches only every nth clock cycle.

### BRIEF DESCRIPTION OF THE DRAWING

The novel features believed characteristic of the invention are set forth in the claims. The invention itself, however, as well as a preferred mode of use, objects and advantages thereof, will best be understood by reference to the following detailed description of an illustrative embodiment when read in conjunction with the accompanying Drawing, wherein:

FIG. 1 is a prior art description of a scan test of logic within an integrated circuit.

FIG. 2 is a simplified diagram of the timing problem as set forth in the prior art.

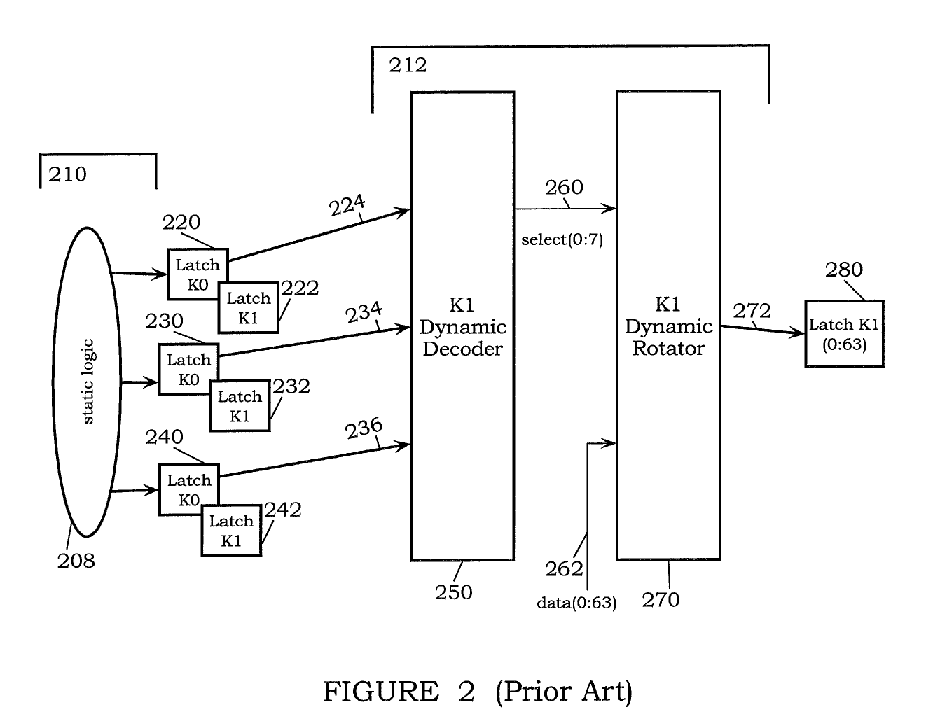

FIG. 3 is a simplified diagram of a prior art attempt to solve the timing problem set forth in FIG. 2.

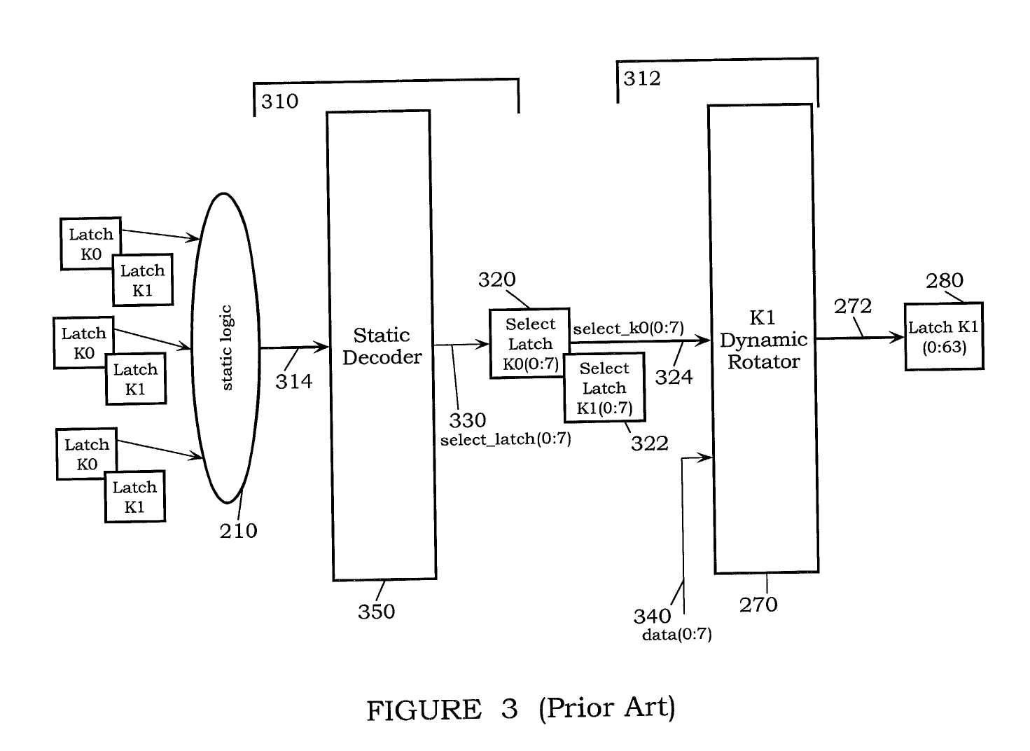

FIG. 4 is a simplified circuit diagram of simultaneous switching concerns in a multiplexer within a rotator of the prior art.

FIG. 5 is a simplified circuit diagram of a technique to solve the simultaneous switching concerns of a scan test in accordance with an embodiment of the invention. It is suggested that FIG. 5 be printed on the face of the patent.

FIG. 6 is a timing diagram of the method to solve the simultaneous switching concerns in accordance with an embodiment of the invention.

FIG. 7 is a timing diagram of the method by which a scan test is blocked in accordance with an embodiment of the invention.

FIG. 8 is a simplified block diagram of a scan test function in accordance with an embodiment of the invention.

### DETAILED DESCRIPTION OF THE INVENTION

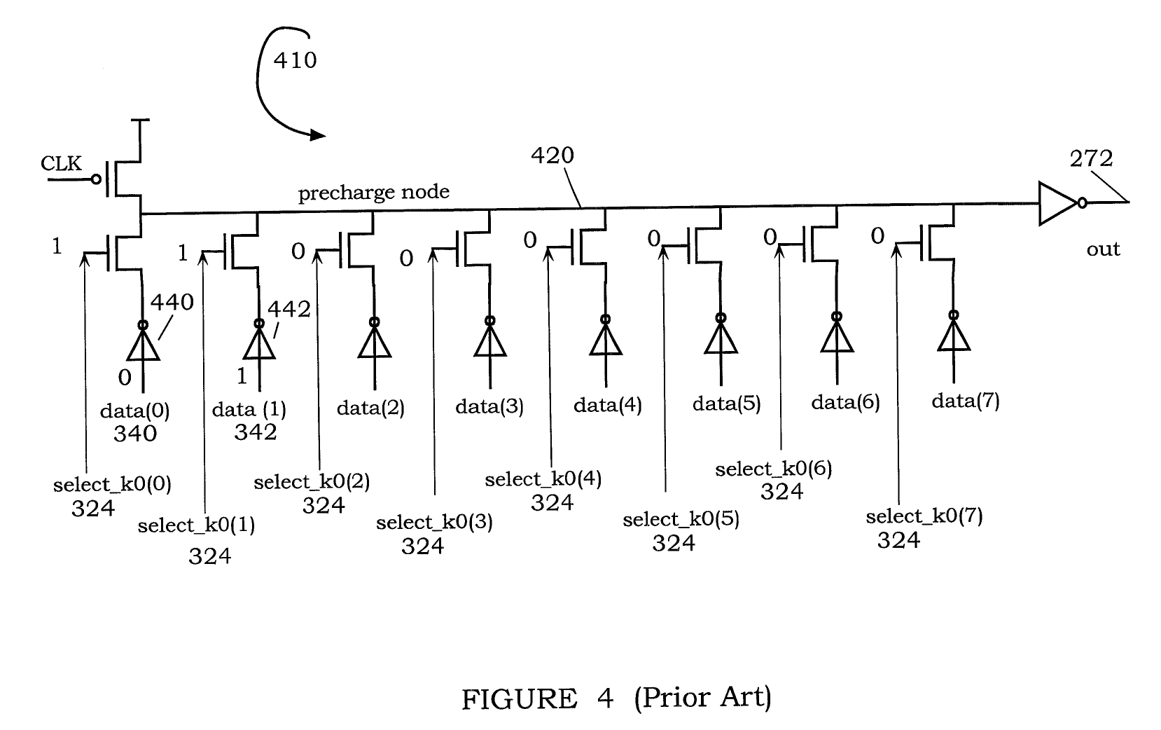

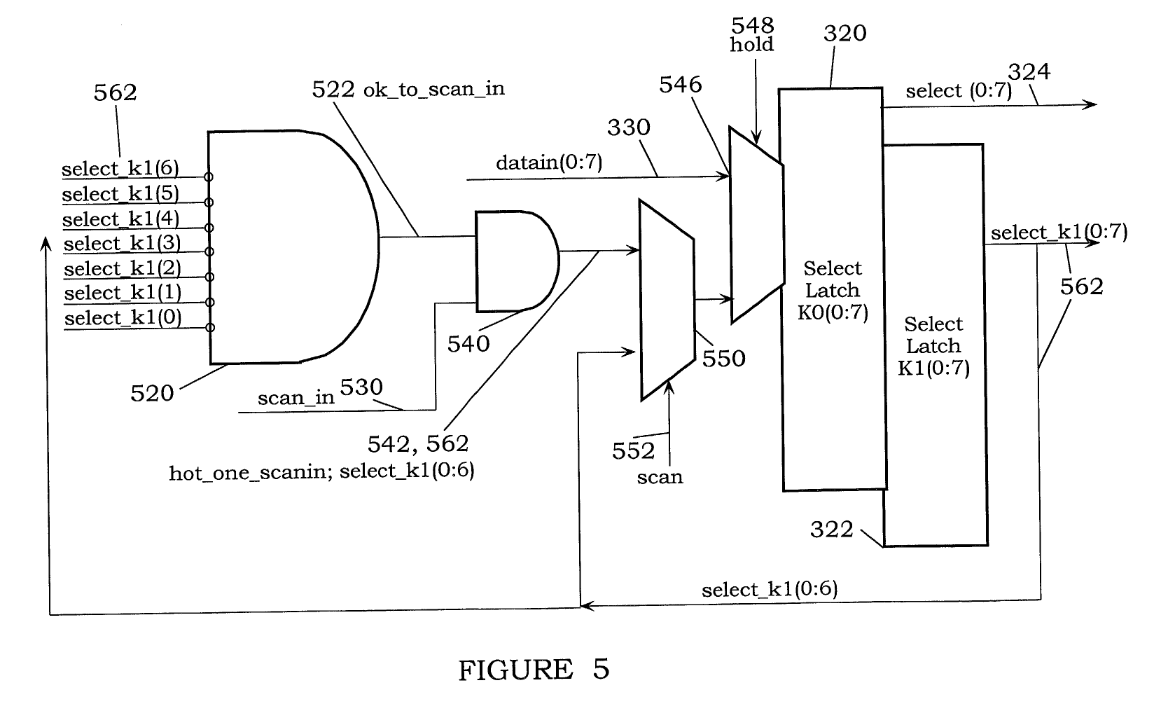

This invention insures the value into a dynamic scannable register will have only allowed values during scan. In the embodiment presented, the allowed values of the scannable register is a “hot one” value and/or all zeros every cycle during scan. An alternative embodiment is that the dynamic register have only a “cold zero” value and/or all ones during every scan cycle; in this embodiment, the inverters of FIGS. 4 and 5 are not required. One of skill in the may realize that other allowable values, such as more than one “hot one” and/or more than one “cold zero”, may be possible depending upon the logic that the signals are feeding. Simply put, the allowed values are those values in the register during scan that prevent contention in a circuit, whether is be a memory or a logic circuit, resulting from simultaneous switching concerns.

FIG. 5 is an illustration of an embodiment of the invention which guarantees that the allowed values as above will be scanned into the dynamic register 320,322 during scan testing such as, but not limited to, during ABIST and LBIST. The signal 562 select_k1(0:6) output from the Select Latch K1 322 is input into a seven way AND gate 520. One of skill in the art with also be aware that an AND gate 520 can be implemented in a variety of logical functions, such as a cascading series of a four-way AND gate and then two two-way AND gates, or an arrangement of NAND, NOR, OR gates, etc. If the signal 324 select_k1(0:6) is not equal to 000000 then the signal 522 ok_to_scan_in will be low. The output signal 522 ok_to_scan_in and the signal 530 scan_in are inputs to a two-way AND gate 540 where the signal 530 scan_in is gated by the signal 522 ok_to_scan_in. If signal 522 ok_to_scan_in is high, then signal 542 hot_one_scanin is set equal to signal 530 scan_in. There are two muxes, a scan mux 550 whose inputs include signal 542 hot_one_scanin and signals 562 select_k1(0:6) or just the signals 562 select_k1(0:7) depending upon the value of a control signal 552 scan. If the control signal 552 scan has a value of zero than the signals 562 select_k1(0:7) are fed into the mux 550. If the control signal 552 scan has a value of one and if the control signal hold 548 of the hold mux 546 also has a value of one, then signal 542 hot_one_scanin is fed into latch 0 and the signals 562 select_k1(0:6) are passed through the muxes 550 and 546 and sequentially loaded into the register 320 which has eight latches in parallel. The output of the register 320 is the signal 324 select_k0(0:7). The output of the register 322 is the signal 562 select_k1(0:7) which is sequentially fed back into the scan mux 550 and is gated by the control signal scan 552. When signal 562 k1_select(0:6)=0000000, signal 522 ok_to_scan_in goes high and if signal 530 scan_in has a value of one, it can 5 be scanned into signal 562 k1_select(0) the next cycle to maintain the hot one requirement.

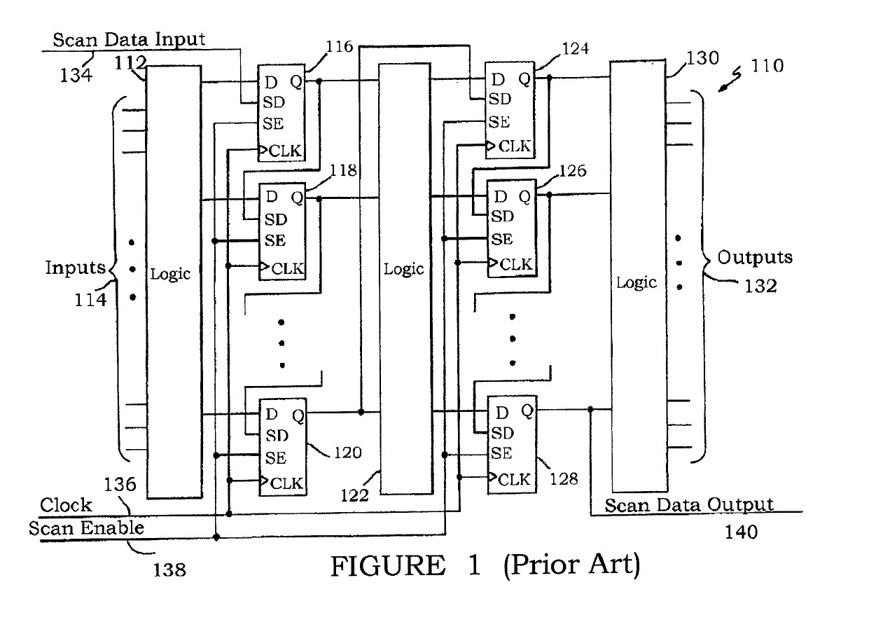

The embodiments presented herein are not limited to only a rotator, or a fixed point unit, or even to a microprocessor. Indeed, the invention will ensure that only values that are allowed can be loaded into any circuit using the basic logic of FIG. 1.

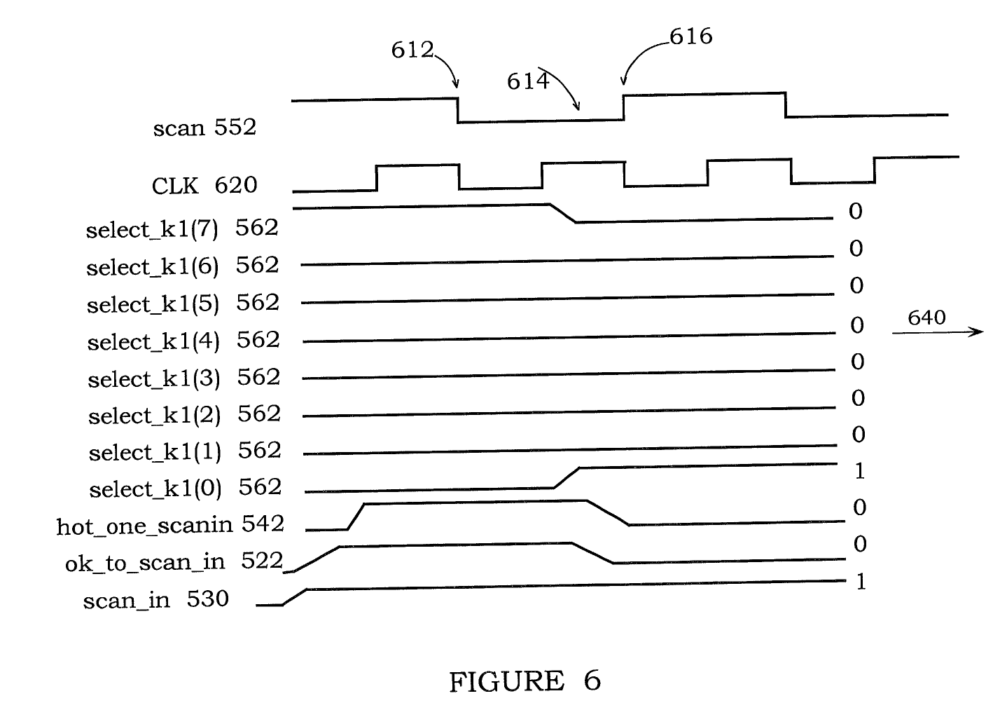

A timing diagram in FIG. 6 shows how the circuit of FIG. 5 works. At the top of the timing diagram, the value of signal 552 scan is shown with three phases: the scan cycle 612 followed by one or more functional cycles 614 to test the chip and then a scan out phase 616 which is shown as having a value of 1. The clock frequency is shown in the timing cycle 620. The values output from the Select Latch K1(0:7) 322 are output as parallel signals 562 select_k1(0:7). During the first cycle of the scan 612 the values of signals 562 select_k1(0:6)=0000000 and select_k1(7) has a value of one. The signals 522 ok_to_scan_in and 530 scan_in go high, then the signal 542 hot_one_scanin is high. Signal 542 hot_one_scanin feeds into the zeroth bit of select_k1 (0) and propagates through the latches. During the scan cycle, the output signals 640 Select(0:7) goes from 00000001 at phase 612 to 10000000 at phase 616 which maintains the hot one requirement.

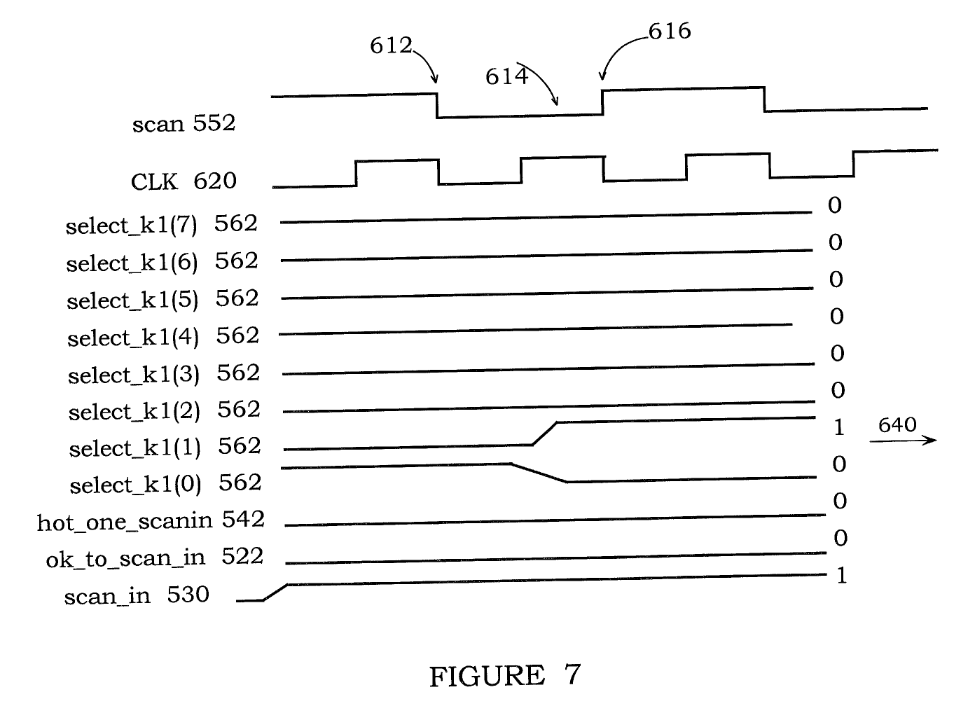

FIG. 7 shows how a circuit in accordance with features of the invention blocks a scanning into a dynamic latch when the signal 562 k1_select(0:6)≠0000000. The timing phases of the scan and clock are the same as in FIG. 6. Note that now signal 562 k1_select(0:6)=1000000 during phase 612 and the value of “1” will propagate through the latches to k1_select(1:7). Note that signal 522 ok_to_scan_in remains low because one of the select bits from 0 to 6 has a value of one. Because signal 522 ok_to_scan_in is low, the value of signal 542 hot_one_scanin is low and a value of 0 is scanned into the zeroth bit k1_select(0). When the scan in during phase 612 ends, the value propagates through the latches so that the signal k1_select(1) now has a value of “1.” During phases 612, 614, and 616, the signal 530 scan_in has a value of “1,” but it is not allowed to scan because signal 522 ok_to_scan_in is zero. Note that during cycle 614, signals 562 select_k1(0:7) goes from 10000000 to 01000000 and the hot one requirement is maintained for the register. Thus, a feature of the invention is that signal 53 scan_in will be allowed every eighth cycle with one of the inputs is a value of “1.” One of skill in the art will realize that the number seven corresponds to an eight-bit register and the invention is not limited to eight bits, eight latches, etc.; but will permit only allowed values into a register, such as a register of any value, such as 256 bits, 64 bits, 1024 bits, etc.

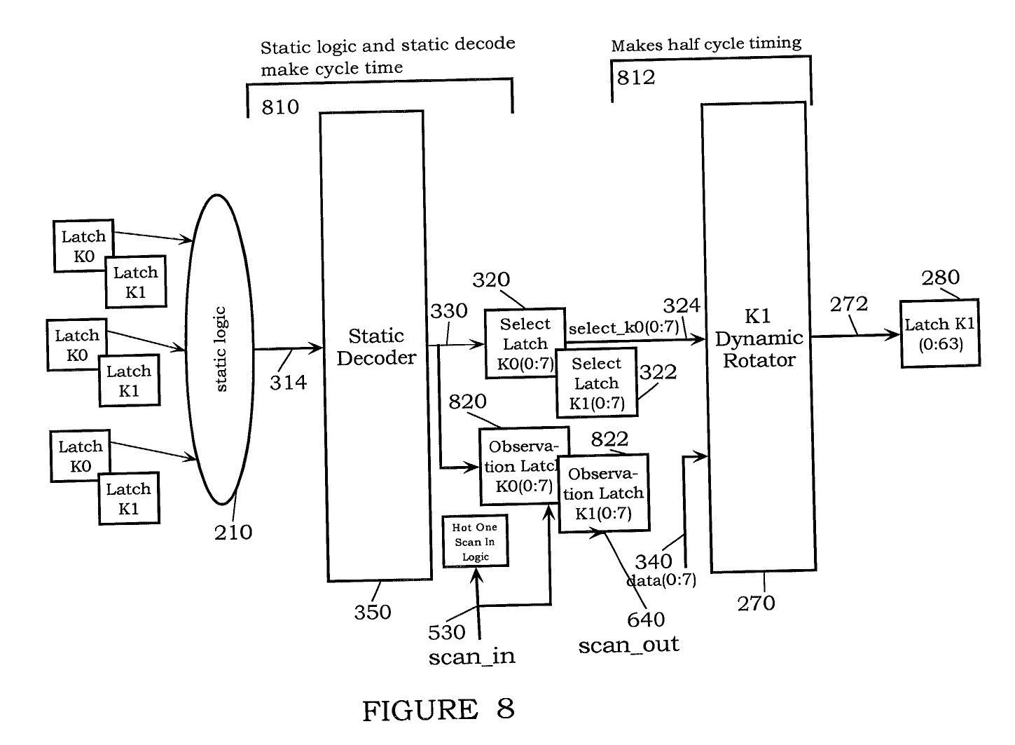

To retain good testability, optional observation latches 820,822 may be added as shown in the simplified circuit of FIG. 8 to receive the output signal 330 of static decoder select_latch(0:7) and make them observable for scan out. Because the observation latches 820, 822 do not change the scan data, the scan out of the observation register is sent to the next latch in the scan ring. Small buffers (not shown) can feed the observation latches 820, 822 to minimize timing penalties. The output of the observation latches 820, 822 are only used for scan purposes and keep the decoder 350 and the static logic 210 in FIG. 8 testable. The designer may decide that adding the observation latches 820, 822 is not important.

While various embodiments of the present invention have been described above, it should be understood that they have been presented by way of example and not limitation and that variations are possible. Thus, the breadth and scope of the present invention should not be limited by any of the above-described exemplary embodiments, but should be defined only in accordance with the following claims and their equivalents.

What is claimed is:

1. A circuit to prevent contention in logic whose input derives from a scannable register, comprising:
(a) a register having a plurality of latches having an input signal;
(b) control logic also having the input signal which gates the input signal to the register so that the register may have only an allowed value; and
(c) a feedback wherein some or all of an output of the register are used to control the control logic.

2. The circuit of claim 1, wherein the allowed value is such that all the latches have a value of zero.

3. The circuit of claim 1, wherein the allowed value is such that only one of the latches has a value of one.

4. The circuit of claim 1, wherein the allowed value is such that all the latches have a value of one.

5. The circuit of claim 1, wherein the allowed value is such that only one of the latches has a value of zero.

6. The circuit of claim 1, wherein the control logic comprises an logical AND function.

7. The circuit of claim 1, wherein the logic in which to prevent contention is dynamic logic.

8. A method to perform a scan test, the method comprising the steps of:
(a) determining acceptable bit values to be scanned into a register that will prevent simultaneous switching;
(b) determining if a scan function is occurring;
(c) determining if any sequence of bits to be scanned into the register of latches is not an acceptable value;
(d) gating the sequence of bits to be scanned into the register;
(e) scanning in an acceptable value into the register;
(f) providing feedback of the bit values in the register;
(g) comparing the bit values in the register to the next bit to be scanned in; and
(h) preventing the next bit from being scanned into the register if it is not an acceptable value.

9. An apparatus for scan test, comprising:
(a) means to scan in bit values for a scan test into a register;
(b) means to determine if any of the bit values in a register will result in a scan test error;
(c) means to determine the bit values in the register during a scan test;
(d) means to provide feedback of the bit values in the register to the scan in means;
(e) means to block admission of a next bit value into the register if the next bit value will result in a scan test error.

10. A method for scan testing a register, comprising the steps of:
(a) ensuring the insertion of a “hot one” bit value into the register of n latches only every nth clock cycle.

11. A method for scan testing a register, comprising the steps of:
(a) ensuring the insertion of a “cold zero” bit value into the register of n latches only every nth clock cycle.
